(19) United States
(12) Patent Application Publication
(10) Pub. No.: US 2021/0375835 A1
(43) Pub. Date: Dec. 2, 2021

(54) NON-PLANAR DISPLAY APPARATUS AND ELECTRONIC DEVICE

(71) Applicant: Shenzhen Royole Technologies Co., Ltd., Shenzhen (CN)

(72) Inventors: Jiahao Kang, Shenzhen (CN); Jigang Zhao, Shenzhen (CN); Shaowen Wang, Shenzhen (CN); Yuan Ze, Shenzhen (CN)

(21) Appl. No.: 17/335,229

(22) Filed: Jun. 1, 2021

(30) Foreign Application Priority Data
Jun. 1, 2020 (CN) 202010486092.4

(51) Int. Cl. H01L 25/075; H01L 33/62; H01L 23/538

(52) U.S. Cl. CPC H01L 25/0753; H01L 23/5387; H01L 33/62

(57) ABSTRACT

This disclosure provides a non-planar display apparatus including a substrate and a plurality of light-emitting elements, the substrate is non-planar and includes a plurality of pixel islands; a spacing is formed between each pair of the plurality of pixel islands, the plurality of pixel islands are mechanically connected, and each pixel island is surrounded by a plurality of spacings; the plurality of pixel islands support subsets of light-emitting elements among the plurality of light-emitting elements, respectively; herein, the plurality of pixel islands form a non-planar surface.

### CROSS REFERENCE TO RELATED APPLICATIONS

This application claims the benefit of Chinese Application No. 202010486092.4, filed Jun. 1, 2020, the entire contents of which are incorporated by reference herein.

### TECHNICAL FIELD

This disclosure relates to the technical field of display, in particular to a non-planar display apparatus and an electronic device.

### BACKGROUND

A flexible display screen is made of flexible materials and can be deformed and bent, advantageous in low power consumption, small size, and the like. In general, the flexible display screen may be folded or rolled to reduce the size of a flexible display apparatus, rendering the flexible display apparatus more portable. The flexible display screen may be unfolded or unrolled when the flexible display apparatus is about to display. Most of the current flexible display screens can only bend along one axis and cannot bend over an entire panel. In the case of a hemispherical display apparatus where light-emitting elements are embedded on a hemispherical support, the pixel density is limited in this way, and it's difficult to realize mass production.

### SUMMARY

It's an object of the disclosure to solve at least one of the technical problems in the related art. To this end, in a first aspect of this application, a non-planar display apparatus is provided, including:

a substrate, where the substrate is non-planar and includes a plurality of pixel islands; a spacing is formed between each pair of the plurality of pixel islands, the plurality of pixel islands are mechanically connected, and each pixel island is surrounded by a plurality of the spacings;

a plurality of light-emitting elements, the plurality of pixel islands supporting each subset of light-emitting elements among the plurality of light-emitting elements;

wherein the plurality of pixel islands form a non-planar surface.

In a second aspect of this application, an electronic device is provided, including the non-planar display apparatus as described above.

This disclosure is advantageous in that a plurality of pixel islands of the non-planar display apparatus form a non-planar surface, and the pixel islands can be distributed in different non-planar configurations through the spacings around each pixel island, so that the non-planar display apparatus can be applied to various non-planar surfaces; moreover, the substrate is provided in the form of the pixel islands, so that the stretchability of the non-planar display apparatus can be improved, and thus the product requirements of different non-planar display apparatuses or different tensile strengths are met.

### BRIEF DESCRIPTION OF THE DRAWINGS

In order that the technical solutions in the embodiments of this disclosure are understood more clearly, the drawings as necessary in the embodiments will be described briefly below. Apparently, the drawings in the following description are only some embodiments of this disclosure. Those of ordinary skill in the art can devise other drawings based on these drawings without inventive efforts.

FIG. 1 is a schematic diagram showing a structure of a non-planar display apparatus according to a first embodiment of this disclosure.

FIG. 2 is a schematic diagram showing the structure of the non-planar display apparatus having a support according to this disclosure.

FIG. 3 is a schematic diagram showing the structure of the non-planar display apparatus having the support according to a second embodiment of this disclosure.

FIG. 4 is a schematic diagram showing a structure of a curved surface according to this disclosure.

FIG. 5 is a schematic diagram showing a structure of another curved surface according to this disclosure.

FIG. 6 is a schematic diagram showing a structure of yet another curved surface according to this disclosure.

FIG. 7 is a schematic diagram of the non-planar display apparatus when unfolded according to this disclosure.

FIG. 8 is a partially enlarged view of portion M of FIG. 7.

FIG. 9 is a schematic diagram of pixel islands connected by control lines according to this disclosure.

FIG. 10 is a schematic diagram showing a structure of a standard light-emitting element composed of sub-light-emitting elements of three adjacent pixel islands according to this disclosure.

FIG. 11 is a schematic diagram showing a structure of one pixel island in the non-planar display apparatus according to a third embodiment of this disclosure.

FIG. 12 is a schematic diagram of a structure having a second connector between pixel islands according to this disclosure.

FIG. 13 is a sectional view taken along line E-E of FIG. 12.

FIG. 14 is a schematic diagram showing the structure of the non-planar display apparatus according to a fourth embodiment of this disclosure.

FIG. 15 is a schematic diagram showing the structure of the non-planar display apparatus according to a fifth embodiment of this disclosure.

FIG. 16 is a schematic diagram showing the structure of the non-planar display apparatus according to a sixth embodiment of this disclosure.

FIG. 17 is a schematic diagram showing the structure of the non-planar display apparatus having a group of first islands according to this disclosure.

FIG. 18 is a schematic diagram showing the structure of the non-planar display apparatus having two first pixel islands between a first pixel island and a second pixel island according to this disclosure.

FIG. 19 is a schematic diagram showing the structure of the non-planar display apparatus having one first pixel island between the first pixel island and the second pixel island according to this disclosure.

FIG. 20 is a schematic diagram showing the structure of the non-planar display apparatus according to a seventh embodiment of this disclosure.

FIG. 21 is a schematic diagram showing the structure of the non-planar display apparatus according to an eighth embodiment of this disclosure.

FIG. 22 is a schematic diagram showing the structure of the non-planar display apparatus according to a ninth embodiment of this disclosure.

FIG. 23 is a schematic diagram showing the structure of the non-planar display apparatus according to a tenth embodiment of this disclosure.

FIG. 24 is a schematic diagram showing the structure of the non-planar display apparatus where the pixel island is circular according to this disclosure.

FIG. 25 is a schematic diagram showing the structure of the non-planar display apparatus according to an eleventh embodiment of this disclosure.

FIG. 26 is a schematic diagram showing the structure of the non-planar display apparatus having an elastic layer according to this disclosure.

FIG. 27 is a flowchart of a method for manufacturing the non-planar display apparatus according to this disclosure.

### DETAILED DESCRIPTION

The following description sets forth the preferred embodiments of this disclosure, and it is to be understood that modifications and adaptations may be devised by those of ordinary skills in the art without departing from the spirit and scope of this disclosure, and these modifications and adaptations shall fall within the scope of this disclosure.

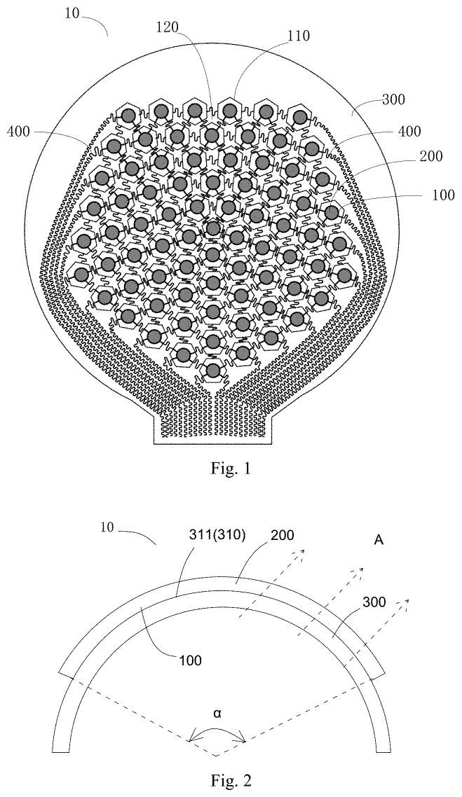

Referring to FIG. 1, a first embodiment of this disclosure provides a non-planar display apparatus 10 including a substrate 100 that is non-planar and includes a plurality of pixel islands 110, and a plurality of light-emitting elements 200; a spacing 120 is formed between each pair of the plurality of pixel islands 110, the plurality of pixel islands 110 are mechanically connected, and each pixel island 110 is surrounded by a plurality of the spacings 120; the plurality of pixel islands 110 support subsets of light-emitting elements among the plurality of light-emitting elements 200, respectively; herein, the plurality of pixel islands 110 form a non-planar surface.

In this application, the substrate 100 is non-planar, and further, the non-planar surface of the substrate 100 is a polyhedron or a curved surface. The polyhedron may be a polyhedron formed by a plurality of polygons with the same or different shapes or a polyhedron formed by a plurality of polygons with the same or different areas, the curved surface may be a curved surface formed by a plurality of curved surfaces with the same curvature or an irregular curved surface, and the irregular curved surface refers to a curved surface spliced by a plurality of curved surfaces with different radii of curvature. The non-planar surface of the substrate 100 may also be an irregularity combined by polygons and surfaces.

Herein, the pixel islands 110 may have the same or different shapes, and the size of the spacings 120 may be configured according to the pixel density of the actual product, that is, the size of the spacings 120 may be configured smaller when the non-planar display apparatus 10 having a larger pixel density is desired, and the size of the spacings 120 may be configured larger when the non-planar display apparatus 10 having a smaller pixel density is desired. The pixel islands 110 are part of the substrate 100, where the spacings 120 are formed by patterning the substrate 100 to remove portions of the substrate corresponding to the spacings 120.

Herein, the subset of the light-emitting elements among the light-emitting elements 200 on the pixel islands 110 may be one sub-light-emitting element or a standard light-emitting element or a plurality of standard light-emitting elements, where the standard light-emitting element includes three sub-light-emitting elements, namely, a red sub-light-emitting element, a green sub-light-emitting element and a blue sub-light-emitting element in the same time. The light-emitting element 200 may be an organic electroluminescent diode or an inorganic light-emitting diode.

Herein, the plurality of pixel islands 110 form the non-planar surface, the plurality of pixel islands 110 may be distributed in a non-planar manner such that the plurality of pixel islands 110 form the non-planar surface. For example, when the plurality of pixel islands 110 are distributed on a support in the form of a hemisphere, the non-planar display apparatus 10 is hemispherical, and when the plurality of pixel islands 110 are distributed on a support in the form of a polyhedron, the non-planar display apparatus 10 is polyhedral, and the plurality of pixel islands 110 spaced apart by the spacings 120 can be adapted to various non-planar support surfaces to form various non-planar display apparatuses.

A plurality of pixel islands 110 of the non-planar display apparatus 10 form the non-planar surface, and the pixel islands 110 can be distributed in different non-planar configurations through the spacings 120 around each pixel island 110, so that the non-planar display apparatus 10 can apply to various non-planar surfaces; moreover, the substrate 100 is provided in the form of the pixel islands 110, so that the stretchability of the non-planar display apparatus 10 can be improved, and thus the product requirements of different non-planar display apparatuses or different tensile strengths are met.

In a further embodiment, the substrate 100 is flexible and variable in shape, and the non-planar surface formed by the plurality of pixel islands 110 varies as the shape of the substrate 100 varies. In this application, the substrate 100 is preferably made of at least one of a flexible organic polymer material (preferably polyimide), ultra-thin glass, and a foil. The substrate 100 may be non-planar in nature or may become non-planar when stretched.

By substrate 100 being flexible and variable in shape, it is meant that substrate 100 as a whole is flexible and variable in shape, substrate 100 may be stretched in various directions such that the size of spacings 120 between pixel islands 110 may be varied, thereby allowing the density of pixel islands 110 to be varied, for example, the substrate 100 may be stretched in each direction to increase the size of spacings 120 when a smaller pixel density is desired. That is, the flexibility and the variable shape of the substrate may render a variable pixel density of the non-planar display apparatus 10.

Referring to FIG. 2, in a further embodiment, the non-planar display apparatus 10 further includes a support 300 having a curved surface 310, and the substrate 100 is disposed on the support 300; side A (where light comes out) of the light-emitting element 200 faces an outer side of the support 300, and a user views from the outer side.

In a further embodiment, the curved surface 310 includes at least one first curved surface 311 positioned on the outer side of the support 300, the substrate 100 is disposed on the at least one first curved surface 311, and the light-emitting element 200 is disposed on a side of the substrate 100 away from the support 300. In this embodiment, the light-emitting element 200 is disposed between the substrate 100 and the side where a user views. Herein, the curved surface 310 includes at least one first curved surface 311, when the curved surface 310 includes only one first curved surface 311, the substrate 100 is provided on the entire curved surface 310, and when there are a plurality of curved surfaces 310 which include one first curved surface 311, the substrate 100 may be provided only on the first curved surface 311.

In a further embodiment, the substrate 100 is fabricated on and separated from a base material and then is disposed on the support 300. That is, to prepare the non-planar display apparatus 10, the substrate 100 may be formed on the base material first, and then the substrate 100 may be separated from the substrate after the light-emitting element 200 and other elements are formed on the substrate 100.

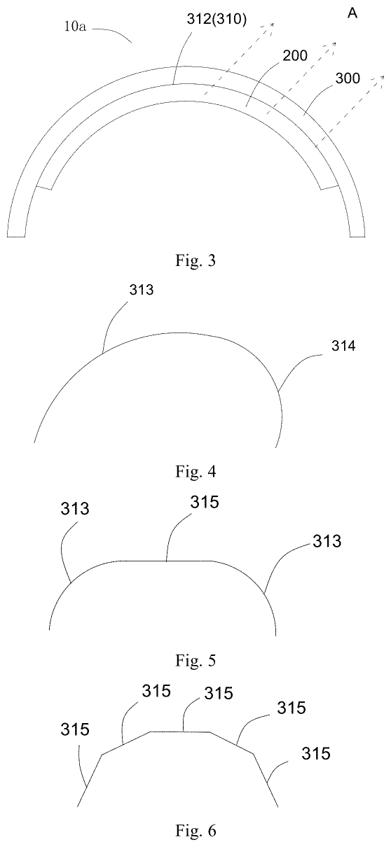

Referring to FIG. 3, a second embodiment of this disclosure provides a non-planar display apparatus 10a. Different from the first embodiment, in the non-planar display apparatus 10a, the curved surface 310 includes at least one second curved surface 312 positioned on an inner side the support 300, the substrate 100 is provided on the at least one second curved surface 312, and the light-emitting element 200 is provided on a side of the substrate 100 opposite the support 300, the support 300 and the substrate 100 being transparent. That is, the light-emitting element 200 and the side A (where light comes out) are provided on both sides of the support 300 or the substrate 100, respectively, and the support 300 and the substrate 100 are configured to be transparent so that light emitted from the light-emitting element 200 can pass through the support 300 and the substrate 100 to reach the user observation side.

Referring to FIGS. 4 to 6, on the basis of the first embodiment, furthermore, the curved surface 310 is formed of at least one of a first sub-curved surface 313, a second sub-curved surface 314, and a plane 315, and curvatures of the first sub-curved surface 313 and the second sub-curved surface 314 are different.

That is, the curved surface 310 may be formed by splicing at least two sub-curved surfaces of different curvatures or by splicing the first sub-curved surface 313 and a plane 315, or by splicing the planes 315 at different angles and presenting an arc. For example, FIG. 4 shows the curved surface 310 spliced by the first sub-curved surface 313 and the second sub-curved surface 314, FIG. 5 shows the curved surface 310 spliced by the first sub-curved surface 313 and the plane 315, and FIG. 6 shows the curved surface 310 spliced by planes 315 at different angles, the curved surface 310 featuring an overall arc.

Referring again to FIG. 3, in a further embodiment, the support 300 is a hemisphere, a sphere, a partial sphere, or an arc; a spherical angle α of the substrate 100 on the support 300 is a preset angular range. In some embodiments, the spherical angle α is 60°≤α≤180°. In other embodiments, the spherical angle α is 180°≤α≤270°. The specific value of the spherical angle α can be set according to an actual product.

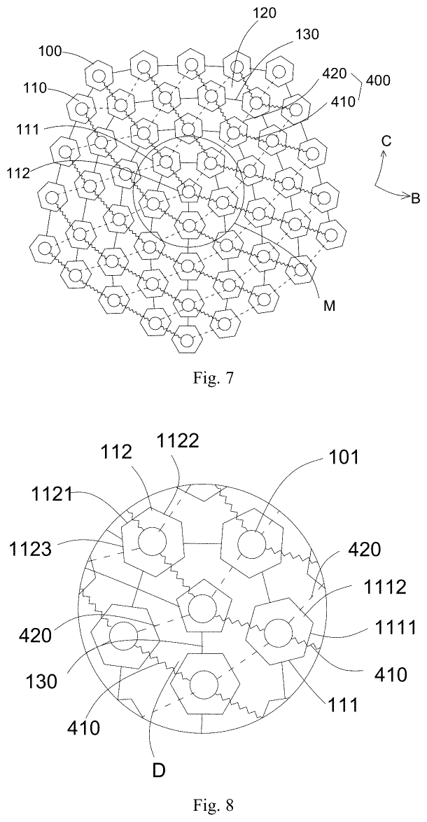

Referring to FIG. 7, in a further embodiment, the substrate 100 further includes a plurality of first connectors 130 connected between two diagonally adjacent pixel islands 110 and positioned in the spacing 120, the first connector 130 being stretchable.

In this application, the plurality of pixel islands 110 are distributed along a row direction B and a column direction C, where the row direction B intersects the column direction C, with an included angle therebetween having a preset angle range; two adjacent pixel islands 110 in the row direction B are called two adjacent pixel islands in the same row, two adjacent pixel islands 110 in the column direction C are called two adjacent pixel islands in the same column, and two adjacent pixel islands 110 between the row direction B and the column direction C are called two diagonally adjacent pixel islands. In this embodiment, the first connector 130 is connected between two diagonally adjacent pixel islands 110. It should be noted that in some embodiments, the row direction B and the column direction C may be reversed.

In a further embodiment, the pixel islands 110 and the first connectors 130 are formed by patterning substrate 100, which is a continuous surface before patterning. That is, the pixel islands 110 and the first connectors 130 are part of the substrate 100, which may be patterned by etching according to the sizes of the pixel islands 110 and the first connectors 130 to obtain the pixel islands 110 and the first connectors 130. Herein, the first connector 130 may be provided in an S-shaped or spring-like configuration to enhance the stretchability of the first connector 130.

In a further embodiment, the non-planar display apparatus 10 further includes a plurality of control lines 400 electrically connecting, for each pixel island 110, subsets of light-emitting elements supported on the pixel island 110, and the plurality of control lines 400 are configured to electrically drive the subsets of light-emitting elements supported by the pixel islands 100; the control lines 400 are also electrically connected to subsets of light-emitting elements on one or more pixel islands 110 adjacent to the respective pixel island 110 in the same row or column. The control line 400 may connect a plurality of adjacent pixel islands 110 in the same row, or the control line 400 may connect a plurality of adjacent pixel islands 110 in the same column. As described above, the row direction B and the column direction C are configured to have an included angle, which is not limited to 90°.

In a further embodiment, the control line 400 includes a first sub-control line 410 and a second sub-control line 420, the first sub-control line 410 being electrically driven and stretchable to connect adjacent pixel islands 110 in the same row, and the second sub-control line 420 being electrically driven and stretchable to connect adjacent pixel islands 110 in the same column.

Herein, one of the first sub-control line 410 and the second sub-control line 420 is a scanning line, and the other is a data line. In this embodiment, both the first sub-control line 410 and the second sub-control line 420 are stretchable so that the size of the spacings 120 around the pixel island 110 can be stretched more uniformly in the row direction B and the column direction C when the non-planar display apparatus 10 is stretched.

In a further embodiment, at least two first sub-control lines 410 intersect at least two second sub-control lines 420 and they collectively form a “#” shaped configuration.

Referring to FIG. 8, in a further embodiment, the pixel islands 110 include first pixel islands 111 having a polygonal shape, and in one first pixel island 111, the first sub-control line 410 connects two first edges 1111 facing one another of the polygonal shape of the first pixel island 111, and a second sub-control line 420 connects two second edges 1112 facing one another of the polygonal shape of the first pixel island 111, the first edge 1111 being different from the second edge 1112. In this embodiment, the first pixel island 111 is hexagonal, with the first edge 1111 disposed adjacent to the second edge 1112. In other embodiments, the first pixel island 111 may have other shapes and the first edge 1111 and the second edge 1112 may be disposed adjacent or spaced apart.

In a further embodiment, the pixel islands 110 further include second pixel islands 112 having a polygonal shape, in one second pixel island 112, the first sub-control line 410 connects two first edges 1121 facing one another of the polygonal shape of the second pixel island 112, and the second sub-control line 420 connects a third edge 1122 and a fourth edge 1123 of the polygonal shape of the second pixel island 112; the third edge 1122 intersects the fourth side 1123, and the first edge 1121 is different from the third edge 1122 or the fourth edge 1123. Herein, the third and fourth edges 1122, 1123 may be disposed adjacent or spaced apart, when the second pixel island 112 is hexagonal, the third and fourth edges 1122, 1123 may be spaced apart (as shown in FIG. 8), when the second pixel island 112 is pentagonal or otherwise shaped, the third and fourth edges 1122, 1123 are spaced apart or disposed adjacent.

In a further embodiment, the first connector 130, the first sub-control line 410, and the second sub-control line 420 enable any three adjacent pixel islands 110 to connect in pairs and form a stretchable triangular structure.

In this embodiment, the pixel islands 110 are hexagonal and the central pixel island 110 is pentagonal. When three hexagonal pixel islands 110 are connected in pairs, the hexagonal pixel islands 110 have three pairs of facing edges, two first connectors 130 are connected between one pair of the three pairs of facing edges of the hexagonal pixel islands 110, the first sub-control line 410 passes through another pair of facing edges of the pixel islands 110, and the second sub-control line 420 passes through the other pair of facing edges of the pixel islands 110; at this time, the adjacent three pixel islands 110 are connected by the first connector 130, the first sub-control line 410 and the second sub-control line 420 to form a stretchable triangular structure, so that the structure of the adjacent three pixel islands 110 is more stable. As shown in FIG. 8, the pentagonal pixel island 110 and two adjacent hexagonal pixel islands 110 are also connected by the first connector 130, the first sub-control line 410, and the second sub-control line 420 to form a stretchable triangular structure D. Three pixel islands 110 of other shapes are also connected by the first connector 130, the first sub-control line 410, and the second sub-control line 420 to form a stretchable triangular structure.

In the case of an entire non-planar display apparatus 10, a plurality of first sub-control lines 410, a plurality of second sub-control lines 420, and a plurality of first connectors 130 form a plurality of triangular structures, thereby forming a net structure, so that the pixel islands 110 can be more stably fixed among the first sub-control lines 410, the second sub-control lines 420, and the first connectors 130, and the structural stability among the pixel islands 110 is improved.

In the case of a single pixel island 110, the first sub-control line 410, the second sub-control line 420, and the first connector 130 are connected around each pixel island 110, and when the non-planar display apparatus 10 is stretched, the first sub-control line 410, the second sub-control line 420, and the first connector 130 simultaneously apply a force to the pixel island 110 to improve the stress uniformity of the pixel island 110 when stretched. When the pixel island 110 is hexagonal and the first sub-control line 410, the second sub-control line 420 and the first connector 130 are uniformly distributed on the six edges of the pixel islands 110, the pixel island 110 may experience more uniform stress when stretched, rendering a more uniform density of the pixel islands 110 in each area of the non-planar display apparatus 10 when stretched.

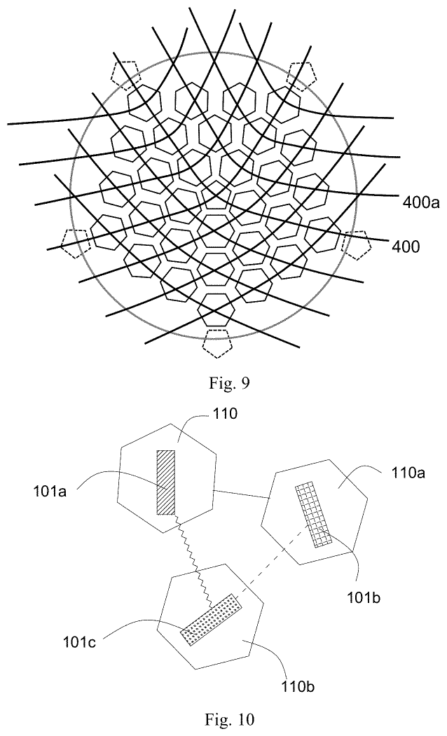

Referring to FIG. 9, in a further embodiment, two adjacent but non-intersecting control lines 400 connect different numbers of pixel islands 100.

The substrate 100 is non-planar, and the pixel islands 110 are also distributed on this non-planar surface, hence the numbers of pixel islands 100 connected by two adjacent control lines 400 along a row direction or a column direction are different. More pixel islands 110 are connected by control lines 400 closer to the center of the non-planar display apparatus 10, and fewer pixel islands 110 are connected by control lines 400 farther from the center of the non-planar display apparatus 10. As shown in FIG. 9, the pixel islands 110 connected by control line 400 are more than the pixel islands 100 connected by control line 400a.

In a further embodiment, when the non-planar display apparatus 10 is stretched, the pixel islands 110 do not vary in lengths in any direction under a first preset stretching force, and the spacings 120 vary in lengths in each direction under a second preset stretching force.

The light-emitting element 200 is configured on the pixel island 110, the light-emitting element 200 generally includes a metal element with poor bending performance, the pixel islands 110 do not vary in lengths in any direction, and thus the light-emitting element 200 is free from damage due to stretching because of the above configuration. Under the second preset stretching force, the spacing 120 varies in lengths in each direction, so that the non-planar display apparatus 10 can be stretched in each direction to adapt to supports 300 of various shapes. Herein, the first preset stretching force and the second preset stretching force are preferably stretching forces applied by stretching the periphery of the entire non-planar display apparatus 10.

In a further embodiment, when the non-planar display apparatus 10 is not stretched, the spacing 120 closer to the center of the non-planar display apparatus 10 has a smaller size; when the non-planar display apparatus 10 is stretched, the first connector 130 and the control line 400 closer to the center of the non-planar display apparatus 10 are subjected to a higher stretching force.

When the non-planar display apparatus 10 is stretched, the stretching force focuses on the center part, therefore, the first connector 130 and the control line 400 closer to the center of the non-planar display apparatus 10 experience a stronger stretching force, which further lengthens the first connector 130 and the control line 400 closer to the center, in other words, increases the size of the spacing 120 closer to the center. To render a more uniform density of the pixel islands 110 in the areas of the stretched non-planar display apparatus 10 close to and far away from the center, the size of the spacing 120 closer to the center of the non-planar display apparatus 10 may be configured smaller when the non-planar display apparatus 10 is not stretched, thereby compensating for the size variation of the spacing 120 close to the center when the non-planar display apparatus 10 is stretched.

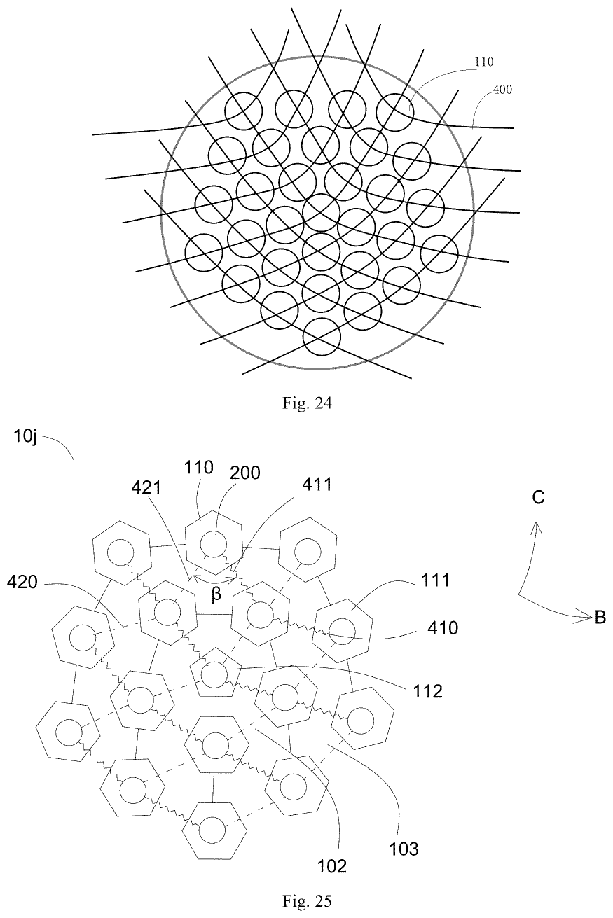

In further embodiments, the shape of the pixel island 110 may be a square, a pentagon, a hexagon, a circle, or an irregular shape. The non-planar display apparatus 10 having circular pixel islands 110 is shown in FIG. 24.

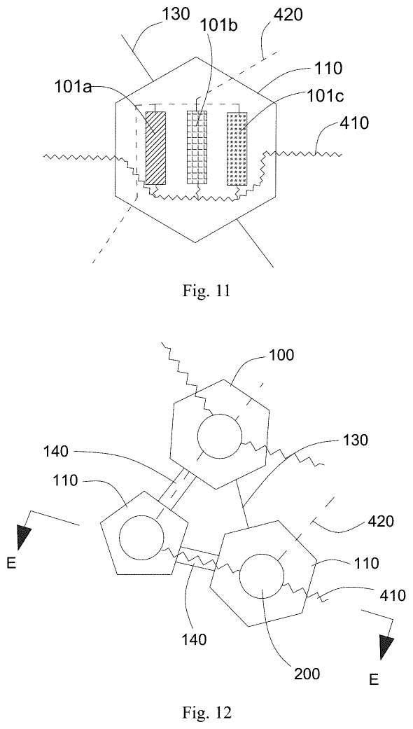

Referring to FIG. 10, in a further embodiment, the subset of light-emitting elements includes one sub-light-emitting element 101, which is one of a red sub-light-emitting element, a green sub-light-emitting element, and a blue sub-light-emitting element. That is, one sub-light-emitting element 101 is provided on each pixel island 110. Three sub-light-emitting elements 101 with different colors are arranged on three adjacent pixel islands 110, respectively, and the three sub-light-emitting elements 101 with different colors form one standard light-emitting element. As shown in FIG. 10, the pixel island 110 is provided with a red sub-light-emitting element 101a, the pixel island 110a is provided with a green sub-light-emitting element 101b, the pixel island 110b is provided with a blue sub-light-emitting element 101c, the pixel island 110, the pixel island 110a and the pixel island 110b are adjacently arranged, and the sub-light-emitting elements on these three pixel islands form one standard light-emitting element.

Referring to FIG. 11, a third embodiment of this disclosure provides a non-planar display apparatus in which, unlike the first embodiment, the subset of light-emitting elements includes at least one standard light-emitting element. That is, at least one standard light-emitting element is provided on each pixel island 110, for example, one standard light-emitting element is provided on each pixel island 110, that is, the red sub-light-emitting element 101a, the green sub-light-emitting element 101b, and the blue sub-light-emitting element 101c are simultaneously provided on each pixel island 110. Alternatively, two or more standard light-emitting elements may be provided on each pixel island 110.

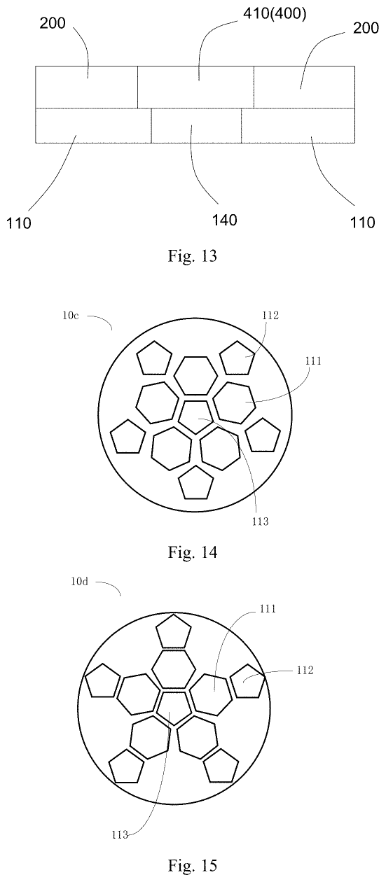

Referring to FIGS. 12 and 13, in a further embodiment, the substrate 100 includes a second connector 140 on which a plurality of control lines 400 are provided; the second connector 140 is formed by patterning the substrate 100. The plurality of control lines 400 may first be formed on the substrate 100, and then the substrate 100 may be etched or otherwise processed to form the second connector 140 according to a routing pattern of the control lines 400. Alternatively, the pixel islands 110, the first connectors 130, and the second connectors 140 may be simultaneously formed by patterning the substrate.

Referring again to FIG. 7, in a further embodiment, the shape of the first pixel island 111 is different from the shape of the second pixel island 112, and the second pixel islands 112 are fewer than the first pixel islands 111.

In a further embodiment, the non-planar display apparatus 10 is configured as a curved surface, at least a portion of the non-planar display apparatus 10 is at least partially conformal to a Goldberg polyhedron, the first pixel island 111 is hexagonal, the second pixel island 112 is pentagonal, the hexagon has a first predetermined size, and the pentagon has a second predetermined size.

Herein, by the at least a portion of the non-planar display apparatus 10 being at least partially conformal to the Goldberg polyhedron, it is meant that at least some of the vertices of the Goldberg polyhedron are on the curved surface of the at least partially non-planar display apparatus 10. The first predetermined size refers to the side length of the hexagon, and the second predetermined size refers to a side length of the pentagon. In this application, a difference between the first predetermined size and the second predetermined size is within a predetermined range so that the first pixel islands 111 and the second pixel islands 112 can be distributed uniformly. Most preferably, the first predetermined size and the second predetermined size are equal.

Referring to FIG. 14, a fourth embodiment of this disclosure provides a non-planar display apparatus 10c in which, unlike the first embodiment, the second pixel island 112 includes a pentagonal central pixel island 113 surrounded by the first pixel islands 111, and any one of the first pixel islands 111 is surrounded by three second pixel islands 112, where the three second pixel islands 112 include the central pixel island 113. Herein, the central pixel island 113 is positioned in the center of the non-planar display apparatus 10. By any one of the first pixel islands 111 being surrounded by three second pixel islands 112, it is meant that any one of the first pixel islands 111 is surrounded by three second pixel islands 112 adjacent to the first pixel islands 111, that is, no other pixel islands are provided between the first pixel island 111 and the three second pixel islands 112; alternatively, any one of the first pixel islands 111 is surrounded by three second pixel islands 112 spaced apart from the first pixel islands 111, that is, other pixel islands may be provided between the first pixel island 111 and the three second pixel islands 112, for example, one or more pixel islands may be provided between the first pixel island 111 and the three second pixel islands 112. In FIG. 14, two adjacent second pixel islands 112 are disposed with a pair of their corners facing one another.

Referring to FIG. 15, a fifth embodiment of this disclosure provides a non-planar display apparatus 10d in which, unlike the first embodiment, the second pixel island 112 includes a pentagonal central pixel island 113 surrounded by the first pixel islands 111; the first pixel island 111 is adjacent to two second pixel islands 112, respectively, on facing sides of the hexagon, and the two second pixel islands 112 include the central pixel island 113. In FIG. 15, two adjacent second pixel islands 112 are disposed with a pair of their edges parallel to each other.

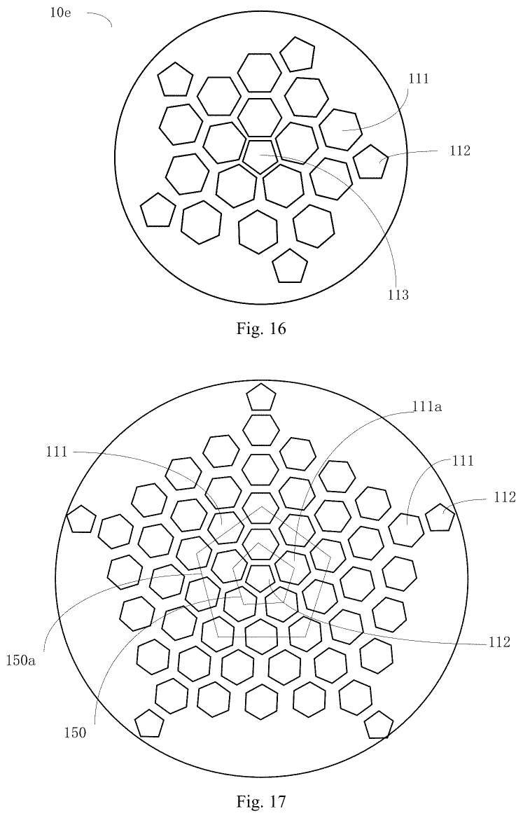

Referring to FIG. 16, a sixth embodiment of this disclosure provides a non-planar display apparatus 10e in which, unlike the first embodiment, each first pixel island 111 is adjacent to one second pixel island 112 on at most only one edge of its hexagon.

Referring to FIG. 17, in a further embodiment, the first pixel islands 111 are disposed around the second pixel island 112, the first pixel islands 111 that are equally distanced from the second pixel island 112 form a group of first islands 150, the non-planar display apparatus 10 includes at least one group of first islands 150, and a group of first islands 150 that are farther from one second pixel island 112 include more first pixel islands 150. As shown in FIG. 17, the group of first islands 150a are farther away from the second pixel island 112 than the group of first islands 150, and the first pixel islands 111 in the group of first islands 150a are more than the first pixel islands 111 in the group of first islands 150.

In a further embodiment, the first pixel island 111 is hexagonal, the second pixel island 112 is pentagonal, and the number of first pixel islands 111 in two adjacent groups of first pixel islands 150 differs by five. As shown in FIG. 17, the number of first pixel islands 111 in the group of first islands 150a differs by five from the number of first pixel islands 111 in the group of first islands 150.

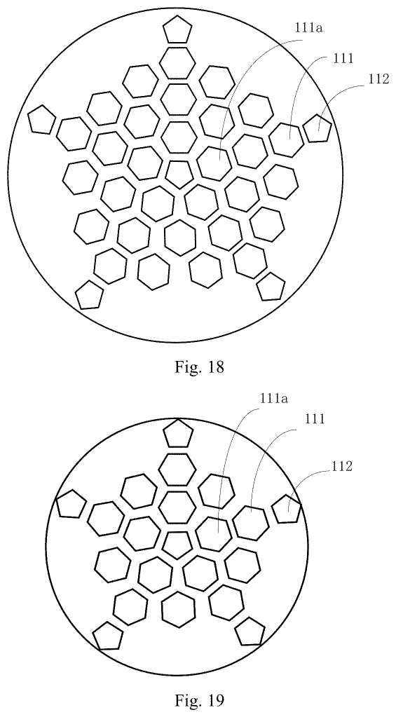

In a further embodiment, at least one first pixel island 111 is surrounded by a plurality of first pixel islands 111, and at least one first pixel island 111 is not adjacent to any one of the second pixel islands 112. As shown in FIG. 17, there are three first pixel islands 111 between the first pixel island 111a and the second pixel island 112, as shown in FIG. 18, there are two first pixel islands 111 between the first pixel island 111a and the second pixel island 112, as shown in FIG. 19, there is also at least one first pixel island 111 between the first pixel island 111 and the second pixel island 112.

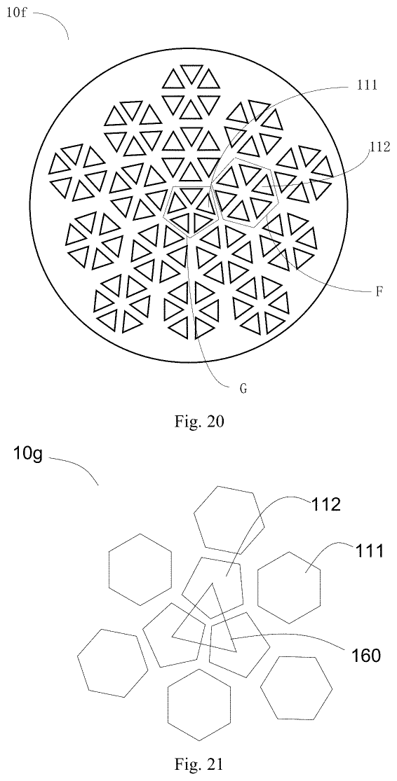

Referring to FIG. 20, a seventh embodiment of this disclosure provides a non-planar display apparatus 10f which, different from the first embodiment, is configured as a curved surface, at least a portion of the non-planar display apparatus 10f is at least partially conformal to a geodesic polyhedron, the first pixel island 111 is an equilateral triangle, and the second pixel island 112 is an isosceles triangle, the side length of the equilateral triangle being equal to the base length of the isosceles triangle. By at least a portion of the non-planar display apparatus 10f being at least partially conformal to the geodesic polyhedron, it is meant that at least some of the vertices of the geodesic polyhedron are on the curved surface of the at least partially non-planar display apparatus 10f. Since the geodesic polyhedron and the Goldberg polyhedron are dual polyhedrons of each other, in some embodiments, six equilateral triangles form a pixel island corresponding to one hexagon F in the first embodiment, and five isosceles triangles form a pixel island corresponding to one pentagon G in the first embodiment.

Referring to FIG. 21, an eighth embodiment of this disclosure provides a non-planar display apparatus 10g in which, unlike the first embodiment, the first pixel island 111 has a hexagonal shape, at least some of the first pixel islands 111 have different sizes, the second pixel island 112 has a pentagonal shape, and three second pixel islands 112 form a group of second pixel islands 160, each group of second pixel islands 160 being surrounded by the first pixel islands 111.

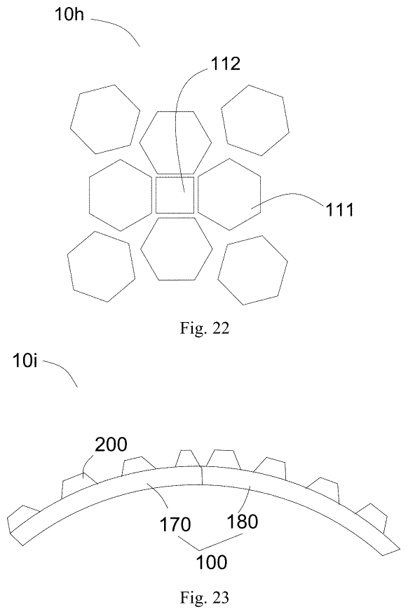

Referring to FIG. 22, a ninth embodiment of this disclosure provides a non-planar display apparatus 10h in which, unlike the first embodiment, the first pixel island 111 has a hexagonal shape, at least some of the first pixel islands 111 have different sizes, the second pixel island 112 has a square shape, and each second pixel island 112 is surrounded by the first pixel islands 111.

Referring to FIG. 23, a tenth embodiment of this disclosure provides a non-planar display apparatus 10i in which, unlike the first embodiment, the substrate 100 includes a first sub-substrate 170 and a second sub-substrate 180 disposed adjacent to each other. The light-emitting elements 200 on the pixel islands 110 in the first sub-substrate 170 and the second sub-substrate 180 are electrically connected and collectively realize luminous display of the non-planar display apparatus 10i. In this embodiment, the substrate 100 is formed by splicing the first sub-substrate 170 and the second sub-substrate 180, and when the first sub-substrate 170 and the second sub-substrate 180 are curved surfaces, the radii of curvature of the first sub-substrate 170 and the second sub-substrate 180 may be the same or different. In some embodiments, one of the first sub-substrate 170 and the second sub-substrate 180 may be curved and the other may be planar.

Referring to FIG. 25, an eleventh embodiment of this disclosure provides a non-planar display apparatus 10j in which, unlike the first embodiment, a plurality of pixel islands 110 form a shape that is at least a portion of a Goldberg polyhedron.

In another embodiment, a plurality of pixel islands 110 form at least a portion of a geodesic polyhedron.

Herein, the Goldberg polyhedron is formed by splicing a plurality of planes, the geodesic polyhedron is also formed by splicing a plurality of planes, that is, the surface of the Goldberg polyhedron or the geodesic polyhedron is not a smooth curved surface, the Goldberg polyhedron and the geodesic polyhedron are dual polyhedrons of each other, and the geodesic polyhedron is obtained by dividing pentagons and hexagons of the Goldberg polyhedron into triangles. The Goldberg polyhedron and the geodesic polyhedron feature tetrahedral symmetry, octahedral symmetry and icosahedral symmetry, by at least a portion of the shape of the non-planar display apparatus 10 in this embodiment being the same as at least a portion of the Goldberg polyhedron or the geodesic polyhedron, it is meant that at least a portion of the shape of the non-planar display apparatus 10 is the same as at least a portion of the Goldberg polyhedron or the geodesic polyhedron featuring any symmetry.

In a further embodiment, the plurality of pixel islands 110 includes a plurality of first pixel islands 111 and one second pixel island 112, where the plurality of first pixel islands 111 are positioned on the Goldberg polyhedron corresponding to places of a plurality of hexagons, respectively, or the plurality of first pixel islands 111 are positioned on the geodesic polyhedron corresponding to places of a plurality of hexagons formed by a plurality of triangles, respectively; the second pixel island 112 is positioned on the Goldberg polyhedron corresponding to the place of a pentagon, or the second pixel island 112 is positioned on the geodesic polyhedron corresponding to the place of a pentagon formed by a plurality of triangles.

When the shape of the non-planar display apparatus 10j is a portion of the Goldberg polyhedron, the first pixel islands 111 are positioned on the Goldberg polyhedron corresponding to places of hexagons, and the second pixel island 112 is positioned on the Goldberg polyhedron corresponding to the place of a pentagon, so that the shape of the non-planar display apparatus 10j forms at least a portion of the Goldberg polyhedron. When the shape of the non-planar display apparatus is a portion of the geodesic polyhedron, the first pixel islands 111 are positioned on the geodesic polyhedron corresponding to places of hexagons formed by a plurality of triangles, and the second pixel island 112 is positioned on the geodesic polyhedron corresponding to the place of a pentagon formed by a plurality of triangles, so that the shape of the non-planar display apparatus forms at least a portion of the geodesic polyhedron.

In a further embodiment, the second pixel island 112 is surrounded by at least five adjacent first pixel islands 111, and the at least five adjacent first pixel islands 111 form a first pentagon 102.

In a further embodiment, a pentagon formed by at least five adjacent first pixel islands 111 is surrounded by at least ten adjacent first pixel islands 111, the at least ten adjacent first pixel islands 111 form a second pentagon 103, and each edge of the first pentagon 102 is disposed adjacent to each edge of the second pentagon 103, correspondingly.

In a further embodiment, the second pixel island 112 is centered by a plurality of first pixel islands 111.

In a further embodiment, the non-planar display apparatus 10j further includes a plurality of control lines 400, the plurality of control lines 400 including first sub-control lines 410 and second sub-control lines 420; some of the first sub-control lines 410 and the second sub-control lines 420 connected between two adjacent pixel islands 110 are first sub-control line segments 411 and second sub-control line segments 421; each pixel island 110 is provided with the first sub-control line segment 411 and the second sub-control line segment 421 that are connected with the light-emitting element 200, and extension lines of the first sub-control line segment 411 and the second sub-control line segment 421 that are connected with the light-emitting element 200 form an included angle (3, the included angle R being larger than 0° and smaller than 90°. Herein, one of the first sub-control line 410 and the second sub-control line 420 is a scanning line, and the other is a data line.

In a further embodiment, the non-planar display apparatus 10j further includes first sub-control lines 410 connecting pixel rows and second sub-control lines 420 connecting pixel columns, the first and second sub-control lines 410, 420 being curved lines. In this embodiment, the pixel rows and the pixel columns are arranged along the curved lines, the pixel rows extending along the first sub-control lines 410, the pixel columns extending along the second sub-control lines 420, in other words, the pixel rows extending in the row direction B in the non-planar display apparatus 10j and the pixel columns extending in the column direction C in the non-planar display apparatus 10j. In the non-planar display apparatus 10j, all the first sub-control lines 410 and the second sub-control lines 420 extend out of the substrate 100 and are bonded to a drive circuit board outside the substrate 100.

In a further embodiment, the pixel islands 110 connected by the first sub-control line 410 through the second pixel island 112 are more than the pixel islands 110 connected by other first sub-control lines 410. Since the second pixel island 112 is centered by the plurality of first pixel islands 111, the pixel islands 110 connected by the first sub-control line 410 through the second pixel island 112 are the most.

In a further embodiment, pixel islands 110 connected by the first sub-control line 410 farther away from the second pixel island are fewer.

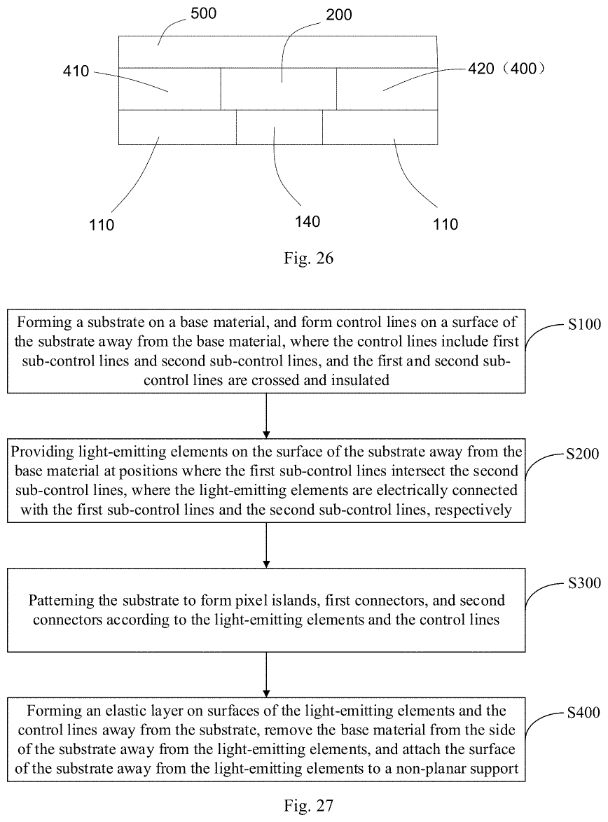

Referring to FIG. 26, in a further embodiment, the non-planar display apparatus 10 further includes an elastic layer 500 disposed on a side of the light-emitting element 200 away from the substrate 100 to cover the light-emitting elements 200 on the substrate 100. Furthermore, the elastic layer 500 covers the light-emitting elements 200 and the control lines 400 on the substrate 10 to protect the light-emitting elements 200 and the control lines 400.

An embodiment of the disclosure also provides an electronic device, including the non-planar display apparatus 10 according to any of the above embodiments.

Referring to FIG. 27, this disclosure also provides a method for manufacturing the non-planar display apparatus, specifically including steps S100, S200, S300, and S400. The details are described as follows.

Step S100, the substrate 100 is formed on a base material, and control lines 400 are formed on a surface of the substrate 100 away from the base material, the control lines 400 include first sub-control lines 410 and second sub-control lines 420, and the first and second sub-control lines 410, 420 are crossed and insulated. Both ends of the control line 400 converge on one side of the substrate 100 to be bonded with a control circuit. The base material is a planar rigid base material.

Step S200, light-emitting elements 200 are provided on the surface of the substrate 100 away from the base material at positions where the first sub-control lines 410 intersect the second sub-control lines 420, and the light-emitting elements 200 are electrically connected with the first sub-control lines 410 and the second sub-control lines 420, respectively.

Step S300, the substrate 100 is patterned to form the pixel islands 110, the first connectors 130, and the second connectors 140 according to the light-emitting elements 200 and the control lines 400. The pixel islands 110 support the light-emitting elements 200, the second connectors 140 support the control lines 400, and the first connectors 130 mechanically connect the pixel islands 110.

Step S400, the elastic layer 500 is formed on surfaces of the light-emitting elements 200 and the control lines 400 away from the substrate 100, the base material is removed from the side of the substrate 100 away from the light-emitting elements 200, and the surface of the substrate 100 away from the light-emitting elements 200 is attached to the non-planar support 300.

The above-described embodiments illustrate only a few embodiments of the disclosure, which are described in detail, but they are not to be construed as limiting the scope of the disclosure. It should be noted that several variations and modifications may be made by those skilled in the art without departing from the spirit of the disclosure and shall fall within the scope of the disclosure. Therefore, the scope of the disclosure shall be defined by the appended claims.

What is claimed is:

1. A non-planar display apparatus, comprising:
a substrate, the substrate being non-planar and comprising a plurality of pixel islands; a spacing formed between each pair of the plurality of pixel islands, the plurality of pixel islands being mechanically connected, and each pixel island surrounded by a plurality of the spacings;
a plurality of light-emitting elements, the plurality of pixel islands supporting each subset of light-emitting elements among the plurality of light-emitting elements;
wherein the plurality of pixel islands form a non-planar surface.

2. The non-planar display apparatus according to claim 1, wherein the substrate is flexible and variable in shape, and the non-planar surface is formed by the plurality of pixel islands varies as the substrate varies in shape.

3. The non-planar display apparatus according to claim 1, wherein the non-planar surface of the substrate is a polyhedron or a curved-surface body.

4. The non-planar display apparatus according to claim 1, further comprising a support having a curved surface, wherein the substrate is disposed on the support, a side where light comes out of the light-emitting element faces an outer side of the support, and the outer side is a user observation side.

5. The non-planar display apparatus according to claim 4, wherein the curved surface comprises at least one first curved surface positioned on the outer side of the support, the substrate disposed on the at least one first curved surface, and the light-emitting element disposed on a side of the substrate away from the support.

6. The non-planar display apparatus according to claim 4, wherein the substrate is fabricated on and separated from a base material, before the substrate disposed on the support.

7. The non-planar display apparatus according to claim 4, wherein the curved surface comprises at least one second curved surface on an inner side of the support, the substrate disposed on the at least one second curved surface, and the light-emitting element disposed on a side of the substrate opposite the support, the support and the substrate being transparent.

8. The non-planar display apparatus according to claim 4, wherein the curved surface is formed of at least one of a first sub-curved surface, a second sub-curved surface, or a plane, and curvatures of the first sub-curved surface and the second sub-curved surface are different.

9. The non-planar display apparatus according to claim 4, wherein the support is a hemisphere, a sphere, a partial sphere, or an arc; a spherical angle of the substrate on the support is in a preset angle range.

10. The non-planar display apparatus according to claim 1, wherein the substrate further comprises a plurality of first connectors, each first connector connected between two diagonally adjacent pixel islands and positioned in the spacing, the first connectors being stretchable.

11. The non-planar display apparatus according to claim 10, wherein the pixel island and the first connector are formed by patterning the substrate, the substrate being a continuous surface before patterning.

12. The non-planar display apparatus according to claim 10, further comprising a plurality of control lines,
the control lines electrically connecting, for each pixel island, subsets of light-emitting elements supported on the pixel island, and configured to electrically drive the subsets of light-emitting elements supported by the pixel islands;
the control lines further being electrically connected to the subset of light-emitting elements on one or more adjacent pixel islands in one row or column.

13. The non-planar display apparatus according to claim 12, wherein the control lines comprise first sub-control lines and second sub-control lines; the first sub-control line electrically driving and being stretchable connected to adjacent pixel islands in one row, and the second sub-control line electrically driving and being stretchable connect to adjacent pixel islands in one column.

14. The non-planar display apparatus according to claim 13, at least two of the first sub-control lines and at least two of the second sub-control lines intersect to form a “#” shape configuration.

15. The non-planar display apparatus according to claim 13, wherein the pixel islands comprise first pixel islands having a polygonal shape, in one of the first pixel islands, the first sub-control line connects two first edges facing one another of the polygonal shape of the first pixel island, the second sub-control line connects two second edges facing one another of the polygonal shape of the first pixel island, and the first edge is different from the second edge.

16. The non-planar display apparatus according to claim 15, wherein the pixel islands further comprise second pixel islands having a polygonal shape, in one of the second pixel islands, the first sub-control line connects two first edges facing one another of the polygonal shape of the second pixel island, the second sub-control line connects a third edge and a fourth edge of the polygonal shape of the second pixel island, the third edge intersects the fourth edge, and the first edge is different from the third edge or the fourth edge.

17. The non-planar display apparatus according to claim 13, wherein the first connector, the first sub-control line, and the second sub-control line enable any three adjacent pixel islands to connect in pairs and form a stretchable triangular structure.

18. The non-planar display apparatus according to claim 12, wherein two adjacent but non-intersecting control lines connect a different number of pixel islands.

19. The non-planar display apparatus according to claim 1, when the non-planar display apparatus is stretched, the lengths of the pixel islands being invariant in any direction under a first preset stretching force, and the spacings varying in lengths in each direction under a second preset stretching force.

20. The non-planar display apparatus according to claim 12, when the non-planar display apparatus is not stretched, the spacing closer to a center of the non-planar display apparatus having a smaller size; when the non-planar display apparatus is stretched, the first connector and the control line closer to the center of the non-planar display apparatus being subjected to a higher stretching force.

21. The non-planar display apparatus according to claim 1, wherein the shape of the pixel island comprises a square, a pentagon, a hexagon, a circle, or an irregular shape.

22. The non-planar display apparatus according to claim 1, wherein the subset of light-emitting elements comprises a sub-light-emitting element, and the sub-light-emitting element is one of a red sub-light-emitting element, a green sub-light-emitting element, and a blue sub-light-emitting element;
three sub-light-emitting elements with different colors being provided on three adjacent pixel islands, and the three sub-light-emitting elements with different colors forming a standard light-emitting element.

23. The non-planar display apparatus according to claim 1, wherein the subset of light-emitting elements comprises at least one standard light-emitting element.

24. The non-planar display apparatus according to claim 12, wherein the substrate comprises a second connector formed by patterning the substrate, and the plurality of control lines are positioned on the second connector.

25. The non-planar display apparatus according to claim 16, wherein the shape of the first pixel island is different from the shape of the second pixel island, and the second pixel islands are fewer than the first pixel islands.

26. The non-planar display apparatus according to claim 25, wherein the non-planar display apparatus is curved, at least a portion of the non-planar display apparatus is at least partially conformal to a Goldberg polyhedron, the first pixel island is a hexagon in a first predetermined size and the second pixel island is a pentagon in a second predetermined size.

27. The non-planar display apparatus according to claim 26, wherein the second pixel islands comprise a pentagonal central pixel island surrounded by the first pixel islands, and any one of the first pixel islands is surrounded by three second islands, wherein the three second pixel islands comprise the central pixel island.

28. The non-planar display apparatus according to claim 26, wherein the second pixel islands comprise a pentagonal central pixel island surrounded by the first pixel islands;
the first pixel island is adjacent to two second pixel islands on two facing sides of the hexagon, and the two second pixel islands comprise the central pixel island.

29. The non-planar display apparatus according to claim 26, wherein each first pixel island is adjacent to one second pixel island at most only one edge of the hexagon.

30. The non-planar display apparatus according to claim 25, wherein the first pixel islands are arranged around the second pixel island, and first islands distanced equally from the second pixel island form a group of first pixel islands, the non-planar display apparatus comprises at least one group of first pixel islands, and the group of first pixel islands farther from the same second pixel island includes more first pixel islands.

31. The non-planar display apparatus according to claim 30, wherein the first pixel island is hexagonal, the second pixel island is pentagonal, and the number of first pixel islands in two adjacent groups of first pixel islands differs by five.

32. The non-planar display apparatus according to claim 25, wherein at least one first pixel island is surrounded by a plurality of first pixel islands, and the at least one first pixel island is not adjacent to any second pixel island.

33. The non-planar display apparatus according to claim 25, wherein the non-planar display apparatus is curved, at least a portion of the non-planar display apparatus is at least partially conformal to a geodesic polyhedron, the first pixel island is an equilateral triangle, the second pixel island is an isosceles triangle, and a side length of the equilateral triangle is equal to a bottom side length of the isosceles triangle.

34. The non-planar display apparatus according to claim 25, wherein the first pixel island is hexagonal, at least some of the first pixel islands differ in sizes, the second pixel island is pentagonal, three second pixel islands form a group of second pixel islands, and each of the second pixel islands is surrounded by the first pixel islands.

35. The non-planar display apparatus according to claim 25, wherein the first pixel island is hexagonal, at least some of the first pixel islands differ in sizes, the second pixel island is square, and each second pixel island is surrounded by the first pixel islands.

36. The non-planar display apparatus according to claim 1, wherein the substrate comprises a first sub-substrate and a second sub-substrate arranged adjacently, the light-emitting elements on pixel islands in the first sub-substrate and the second sub-substrate are electrically connected and collectively realize luminous display of the non-planar display apparatus.

37. The non-planar display apparatus according to claim 1, wherein a plurality of the pixel islands form at least a portion of the Goldberg polyhedron or the geodesic polyhedron.

38. The non-planar display apparatus according to claim 37, wherein the plurality of pixel islands comprises a plurality of first pixel islands and one second pixel island, the plurality of first pixel islands are positioned on the Goldberg polyhedron corresponding to places of a plurality of hexagons, respectively, or the plurality of first pixel islands are positioned on the geodesic polyhedron corresponding to places of a plurality of hexagons formed by a plurality of triangles, respectively;
the second pixel island is positioned on the Goldberg polyhedron corresponding to a place of a pentagon or the second pixel island is positioned on the geodesic polyhedron corresponding to a place of a pentagon formed by a plurality of triangles.

39. The non-planar display apparatus according to claim 38, wherein the second pixel island is surrounded by at least five adjacent first pixel islands, and the at least five adjacent first pixel islands form a first pentagon.

40. The non-planar display apparatus according to claim 39, wherein the pentagon formed by at least five adjacent first pixel islands is surrounded by at least ten adjacent first pixel islands, the at least ten adjacent first pixel islands form a second pentagon, and each side of the first pentagon is disposed adjacent to each side of the second pentagon correspondingly.

41. The non-planar display apparatus according to claim 38, wherein the second pixel island is centered by a plurality of the first pixel islands.

42. The non-planar display apparatus according to claim 38, further comprising a plurality of control lines, wherein the control lines comprise first sub-control lines and second sub-control lines;
some of the first sub-control lines and the second sub-control lines connected between two adjacent pixel islands being first sub-control line segments and second sub-control line segments, respectively;
each pixel island provided with the first sub-control line segment and the second sub-control line segment that being connected with the light-emitting element, and extension lines of the first sub-control line segment and the second sub-control line segment that being connected with the light-emitting element form an included angle, the included angle being larger than 0° and smaller than 90°.

43. The non-planar display apparatus according to claim 38, further comprising first sub-control lines connecting pixel rows and second sub-control lines connecting pixel columns, the first and second sub-control lines being curved lines.

44. The non-planar display apparatus according to claim 43, the pixel islands connected by the first sub-control line through the second pixel island being more than the pixel islands connected by other first sub-control lines.

45. The non-planar display apparatus according to claim 43, the pixel islands connected by the first sub-control line farther away from the second pixel island being fewer.

46. The non-planar display apparatus according to claim 1, further comprising: an elastic layer, provided on a side of the light-emitting elements away from the substrate to cover the light-emitting elements on the substrate.

47. An electronic device, comprising the non-planar display apparatus;
wherein the non-planar display apparatus comprises:
a substrate, wherein the substrate is non-planar and comprises a plurality of pixel islands; a spacing is formed between each pair of the plurality of pixel islands, the plurality of pixel islands are mechanically connected, and each pixel island is surrounded by a plurality of the spacings;
a plurality of light-emitting elements, the plurality of pixel islands supporting each subset of light-emitting elements among the plurality of light-emitting elements;
wherein the plurality of pixel islands form a non-planar surface.
